(19) United States
(12) Patent Application Publication
(10) Pub. No.: US 2026/0192345 A1
(43) Pub. Date: Jul. 9, 2026

(54) METHOD AND DEVICE FOR PROCESSING A SOLAR MODULE

(71) Applicant: SOLAR MATERIALS GMBH, Magdeburg (DE)

(72) Inventors: Jan BARGEL, Magdeburg (DE); Fridolin FRANKE, Braunschweig (DE); Jan-Philipp MAI, Braunschweig (DE)

(21) Appl. No.: 19/131,687

(22) PCT Filed: Nov. 20, 2023
(86) PCT No.: PCT/EP2023/082369

§ 371 Date: May 21, 2025

(30) Foreign Application Priority Data
Nov. 23, 2022 (DE) 10 2022 130 988.6

(51) Int. Cl. B09B 3/35; B09B 101/15

(52) U.S. Cl. CPC B09B 3/35; B09B 2101/15

(57) ABSTRACT

The invention relates to a method for processing a solar module, wherein the solar module comprises—at least one silicon main body (2) having a charge-doped zone a hole-doped zone and a first surface and—first metallic conductor tracks (4) on the first surface of the main body (2), wherein the method comprises the following steps: a) providing a prepared solar module in which the first metallic conductor tracks (4) are accessible from outside, b) removing a removal portion of the main body (2), wherein the first metallic conductor tracks (4) are situated on the removal portion, c) collecting the removed material.

The invention relates to a method for processing a solar module, the solar module having at least one silicon main body with a charge-doped zone, a hole-doped zone and a first surface and first metallic conductor tracks on the first surface of the main body. The invention also relates to a device for conducting such a method.

Solar modules of the type mentioned above are being used in increasing numbers to generate electricity from sunlight. For example, said solar modules may be placed in small numbers on roofs of private buildings, such as residential buildings, in order to at least partially meet the electricity demand of the house on which the solar modules are mounted. This use of this kind of decentralized energy supply is increasing, for example to charge electric vehicles decentrally. However, solar modules of the type mentioned above are also used in large installations on otherwise agricultural land to generate commercial electricity and feed it into the public grid.

The disadvantage is that the solar modules only have a limited service life. Expensive raw materials are used during production of the solar modules. For example, the conductor tracks are manufactured from a large number of modules made of silver. For this reason alone, there is a need for a method that recycles said raw materials and makes them available for reprocessing. However, the growing number of solar modules that reach the end of their service life and are discarded also creates a large amount of waste, which should be recycled or at least treated, particularly in view of the environmental compatibility of electricity generation, of which solar modules and the generation of electricity from sunlight are emblematic. For solar modules which contain metal components arranged on a glass substrate, JP 2014/054593 A proposes a method in which the components are mechanically removed. The glass described in said publication is capable of withstanding mechanical stress, which is precisely why these substrates are described and disclosed there. For other substrates, the only processes known thus far from the prior art use wet chemical processes, which are disadvantageous due to the high costs, the substances used, which are often harmful to the environment and/or health, and the high degree of effort involved.

The main body of a solar module has an upper side which faces the light to be intercepted during operation of the solar module and is usually covered with a cover layer made of glass or another material. This cover layer is preferably transparent or at least partially transparent for the light to be intercepted. The main body also comprises a lower side opposite the upper side. The lower side is preferably covered by a carrier layer. This preferably means that the lower side of the main body is arranged on the carrier layer. Metallic conductor tracks can be arranged on both the upper and lower side of the main body. Metallic conductor tracks on the upper side are preferably located between the upper side of the main body and the cover layer. Metallic conductor tracks on the lower side are preferably located between the lower side of the main body and the carrier layer. In both cases, further layers or materials may be arranged between the main body and the cover layer or the carrier layer. For example, this is an adhesive layer.

The invention is therefore based on the task of proposing a method with which that the disadvantages of the prior art can be eliminated or at least reduced.

The invention solves the addressed task by way of a method of the type described at the beginning, which comprises the following steps:
a) providing a prepared solar module where the first metallic conductor tracks can be accessed from the outside,
b) removing a removal portion of the main body, wherein the first metallic conductor tracks are situated on the removal portion,
c) collecting the removed material.

Any carrier layers or cover layers, such as coverslips or protective layers against mechanical damage that many solar modules have, have been removed from the prepared solar module. This can be done during a method of the type described here and will be described in detail later. However, it is also possible to start the method with a correspondingly prepared solar module, rather than carry out this preparation within the scope of the method described here. Such a module can be purchased externally, for example.

The first surface can be the upper side of the main body. The first metallic conductor tracks are then the conductor tracks that are arranged on the upper side of the main body. They can also be referred to as upper conductor tracks. However, the first surface can also be the lower side of the main body. The first metallic conductor tracks are then the conductor tracks that are arranged on the lower side of the main body. They can also be referred to as lower conductor tracks. It is irrelevant for the method whether upper or lower conductor tracks are considered as first conductor tracks. It is important that the solar module is prepared in such a way that said first conductor tracks can be accessed from the outside. To this end, a cover layer has been removed if the first conductor tracks are upper conductor tracks, and a carrier layer has been removed if the first conductor tracks are lower conductor tracks.

In the case of a prepared solar module, the first conductor tracks can be accessed from the outside. Specifically, this means that they are not covered by a solid layer, such as glass or plastic. However, it does not necessarily mean that the conductor tracks cannot be covered at all, even though this does represent the preferred embodiment. It is absolutely possible that the conductor tracks are covered by an adhesive layer or the remains or parts thereof that were required or used to attach a cover layer or carrier layer. It is only important that the conductor tracks can be accessed in such a way that they can be removed with the section of the main body underneath the conductor tracks using a removal tool.

This is done in step b) of the method. A removal portion of the main body is removed where the first metallic conductor tracks are situated. The removal portion thus contains, in particular, the part of the first surface of the main body where the first conductor tracks are arranged. It is important for the process that as much of the first surface as possible, where there are no conductor tracks, is not removed. This increases the proportion of the metal in the removed material. During removal, a small cut or groove is introduced into the first surface of the main body. It is usually equipped with irregular rims and edges, as the material that is removed is preferably broken out of the main body. Rather than referring to a groove or cut, it could also be said that a depression is made in the first upper side. The depression preferably extends along the path along which the conductor tracks were arranged on the first surface. The depression is preferably at most twice as wide as the conductor track. As described above, the first surface can be the upper side or the lower side of the main body.

The removed material is collected and fed for further processing. Said further processing is performed, for example, in a separation device in which the metal of the metallic conductor tracks is separated from the silicon of the main body that has also been removed. From an economic perspective, the metal of the metallic conductor tracks is the interesting aspect. It is therefore advantageous to keep the proportion of silicon in the collected material as low as possible. The depth of the depression introduced into the first surface during removal is preferably small, for example smaller than 1 cm, preferably smaller than 5 mm, especially preferably smaller than 2 mm.

Preferably, a removal tool is used to remove the removal portion, said tool penetrating with a penetration element into the main body and breaking out the removal portion. The removal tool is preferably a milling tool, a wedge or a blade. A rolling removal tool, similar to a pizza roller used to cut a pizza, can also be used.

It is beneficial if the removal tool comprises a penetration element that penetrates into the main body, thereby breaking out the material to be collected. For example, the penetration element penetrates into the first surface.

The penetration element preferably penetrates into a lateral surface of the main body or through the first surface of the main body. The main body has a first surface and a second surface opposite the first surface. A lateral surface that connects the two surfaces is located between the first surface and the second surface. The penetration of the penetration element into said lateral surface means that the depth of the depression to be created can be set easily and precisely. A penetration element is preferably designed to be wedge-shaped, i.e. it has an increasing thickness in at least one direction. The penetration element then preferably penetrates with a thin side, i.e. with a small thickness, into the main body. Due to the increasing thickness of the penetration element, it breaks material out of the main body in the process and moves said material upwards.

In one preferred embodiment, the removal tool comprises two penetration elements, each of which penetrates into the main body on one side of the metallic conductor tracks, so that the removal portion lies between the two penetration elements. In this configuration, it is advantageous, but not essential, for the penetration elements to penetrate into the first surface of the main body. It is particularly preferable for the two penetration elements to run conically towards each other in the direction of penetration. The distance between the two penetration elements thus decreases as the penetration depth increases. As a result, the material of the main body situated between them is especially easy to break out.

Advantageously, the main body has a second surface opposite the first surface on which second metallic conductor tracks are located, wherein the removal portion contains part of the first surface with the first metallic conductor tracks and part of the second surface with the second metallic conductor tracks. This increases the yield of metal and renders the method economically viable. When the upper side of the main body forms the first surface, the second surface is the lower side of the main body and vice-versa.

The first metallic conductor tracks and the second metallic conductor tracks preferably lie opposite one another. This means that the depression to be made during removal extends through the entire main body, i.e. from the first surface to the second surface, and both the first and second conductor tracks can be removed as a result. It does not mean that wherever first conductor tracks are located on the first surface, second conductor tracks are also arranged on the second surface, but preferably first conductor tracks are positioned on the first surface at the points opposite to where second conductor tracks are located on the second surface of the main body. Preferably, there are fewer second conductor tracks on the second surface than first conductor tracks on the first surface. Even if the tip of the penetration element does not necessarily penetrate into the main body, but also, for example, into the second conductor tracks or a layer still underneath, for example a carrier layer or a cover layer, within the scope of the present invention it is said that the penetration element penetrates into the main body.

Advantageously, the second conductor tracks are covered by a carrier layer, preferably made of a plastic. This carrier layer may be damaged during removal of the removal portion, so that carrier layer material may also be found in the collected material. The carrier layer ensures that the solar module does not break or remaining parts of the solar module do not separate from each other even if the depression made in the main body during removal cuts completely through the main body.

In one preferred embodiment, the solar module has a cover layer that is at least partially transparent to visible light, preferably transparent to visible light, and at least one adhesive layer arranged between the cover layer and the first metallic conductor tracks, wherein the provision of the prepared solar module includes heating the at least one adhesive layer and subsequently removing the cover layer from the main body.

Preferably, the adhesive layer is heated by means of infrared radiation and/or magnetic induction and/or by means of microwave radiation. Heating is carried out to a temperature of more than 180° C., preferably more than 200° C., especially preferably more than 230° C. and less than 400° C., preferably less than 350° C., especially preferably less than 280° C. Particularly when using infrared radiation or microwave radiation, it is advantageous to apply the radiation through the cover layer, which is preferably at least partially, but preferably fully, transparent to the respective type of radiation. Infrared radiation used for this purpose preferably has a wavelength between 1000 and 4000 nm, preferably from 2000 to 2500 nm. The preferred temperature is below 400° C. Above this temperature, pyrolysis occurs, during which toxic and environmentally harmful gases are released. This can be avoided with a temperature below 400° C. At a temperature of more than 180° C., preferably more than 200° C., acetic acid is preferably released in the adhesive layer, which creates a lubricating film between the layers connected by the adhesive layer, i.e. preferably the main body and the cover layer. This causes forces of adhesion, which are applied by the adhesive layer, to decrease and the two connected elements can be separated from each other. Preferably, at least one film of ethylene vinyl acetate (EVA) is also used as an adhesive layer, which releases acetic acid when heated in the temperature range mentioned.

Once the adhesive layer has been heated to the desired temperature, either the heat source can be switched off or controlled such that the temperature is kept constant for a certain amount of time, for example 10 minutes, in order to process the solar module at this temperature. Heating is preferably done across the full surface so that the entire adhesive layer of the solar module to be processed is heated evenly. Alternatively, it is also possible to heat part of the adhesive layer and, for example, to move the heat source relative to the solar module or vice-versa. During heating, the solar module is preferably in a vacuum, i.e. it is subjected to a negative pressure. However, heating under normal pressure is also possible.

If electromagnetic radiation is used as a heat source, it can be introduced directly into the adhesive layer to be heated through the cover layer, which is at least partially transparent to said radiation. This is different when using magnetic induction, as the adhesive layer is generally not magnetic or cannot generally be magnetized. In this case, the magnetic induction field causes another layer of the solar module to be heated, preferably the main body, which can also be referred to as a substrate or wafer, so that it then emits heat to the adhesive layer arranged on it.

Lasers can also be used in addition or as an alternative to the heat sources mentioned, in order to heat the at least one adhesive layer.

In one preferred embodiment, the cover layer is removed from the main body by applying opposing tensile forces to the cover layer and the main body. In this case, the opposing tensile forces can be applied perpendicular to the upper side of the main body. For a solar module lying on a work surface, this means that the tensile forces act upwards and downwards. Negative pressure elements, such as suction elements, are preferably used for this purpose. The substrate is preferably positioned on a work surface that has openings which are then sealed by the substrate. By applying a negative pressure or a suction force to the sealed openings, a suction force and therefore a tensile force is exerted on the substrate that holds it on the work surface. Preferably at least one suction element or at least one suction pad is applied to the cover layer which is configured to apply a suction force to the cover layer, which is directed away from the work surface, i.e. it generally acts upwards. As a result, two opposing forces are applied and the cover layer is separated from the substrate.

Alternatively or additionally, at least one slide is used to apply a force to the cover layer that acts parallel to the work surface on which the substrate is arranged. The substrate is preferably held in place by the previously described suction force on the work surface. Alternatively or additionally, the work surface has an end stop, which protrudes from the work surface and rests on the substrate. The substrate rests on the end stop in such a way that a movement of the substrate, which has been caused by the force applied by the slide, is prevented and is not possible. If the slide applies a force to a first lateral surface of the cover layer, the substrate preferably rests with the opposite side on the projection.

Alternatively, the opposing tensile forces can also be applied parallel to the upper side of the main body. This results in shear forces, by means of which the two components can be separated from each other.

In a preferred embodiment, the cover layer is damaged or destroyed before the adhesive layer is heated or before the cover layer is removed from the base body. In the process, the cover layer is preferably divided into several parts by mechanical stress. For example, this can be achieved by striking the cover layer with, for example, a hammer. The cover layer is then in multiple individual parts, most of which, but preferably all of which, are still joined to the main body via the adhesive layer. The individual parts can then be removed from the main body in the ways described above.

If the cover layer and the main body are separated from each other in such a way that they are moved in parallel, few bending moments are applied to the main body in particular, on the upper side of which the conductor tracks are located, so that the risk of the main body breaking is reduced. This has the advantage of mechanically removing the conductor tracks from the main body, which is all the easier the less mechanically damaged the main body is.

Preferably, before removing the cover layer, the cover layer is damaged by means of a tool, preferably a spatula, scraper, knife or wire, the tool preferably being inserted between the cover layer and the main body. Contrary to what happens with the main body, which is preferably undamaged and bears no cracks after the cover surface has been removed, the cover layer is completely damaged in order to be able to remove individual parts of the cover layer more easily.

Preferably, the at least one adhesive layer is also at least partially, but preferably fully, removed when the cover layer is removed. This means that as few sections of the adhesive layer as possible remain on the upper side of the main body and thus on the conductor tracks. These sections would be removed during removal of the removal portion and collected with the removed material.

The adhesive layer is therefore preferably at least partially, but preferably fully, removed once the cover layer has been removed. In this case, it may be advantageous to re-heat the remaining sections of the adhesive layer if the adhesive layer is no longer warm enough. Particularly preferably, a mechanical tool, such as a wire, spatula, scraper, blade, knife or brush, is used for removing the at least one adhesive layer after removing the cover layer.

The removed material is collected. Preferably, it is suctioned up and collected in a container. For this purpose, it is advantageous if the tool used for removal is already inside a box or bell, so that the removed dust can be collected as easily as possible. The material can be collected with an air flow or a liquid flow, for example composed of water or an oil. However, preferably no liquid is used as the removed chips or dust have to be subsequently dried.

The invention solves the addressed task by way of a device for performing a method described here which comprises a removal tool and a collection device. The device preferably has at least one heating device for heating the at least one adhesive layer and at least one traction device for applying a tensile force. Preferably, the traction device has at least one, preferably several vacuum grippers and/or at least one, preferably several Bernoulli grips.

In one preferred embodiment, the device also has an electric control unit and the removal tool has at least one mechanical tool, wherein the electric control unit is configured to control at least one operating parameter of the at least one mechanical tool. The at least one operating parameter is preferably a contact pressure, a path or a force. The electric control unit is preferably an electronic data processing device, which is preferably part of the device. However, it is also sufficient if the electronic data processing device is not part of the device, but the device communicates with the electronic data processing device via a communication device.

An embodiment example of the invention will be explained in more detail with the aid of the accompanying drawing. It shows:

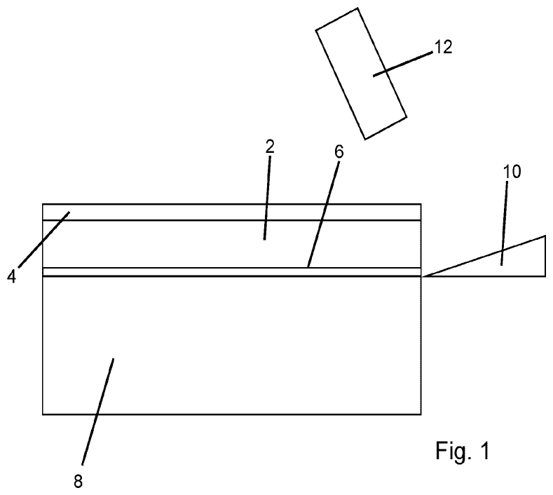

FIG. 1—the schematic representation of a solar module with removal tool and collection device.

FIG. 1 shows a prepared solar module. It has a main body 2 with first conductor tracks 4 situated on its first surface. Second conductor tracks 6 are shown on the opposite second surface. In the embodiment example shown, a carrier layer 8 is situated beneath. In the embodiment example shown, the first surface of the main body is the upper side of the main body. In the embodiment example shown, the second surface of the main body is the lower side of the main body. This is advantageous, but not essential. To be able to recycle the first conductor tracks 4 and the second conductor tracks 6, the illustrated penetration element 10 of a removal tool is penetrated into the main body. In the embodiment example shown, this is done in such a way that the penetration element penetrates between the second conductor track 6 and the carrier layer 8 and, due to its wedge shape, breaks the layers above, thus removing them. The material removed in this way is collected suction 12 and fed for further processing.

### REFERENCE LIST

2 main body
4 first conductor tracks
6 second conductor tracks
8 carrier layer
10 penetration element
12 suction

1. A method for processing a solar module, the solar module, comprising
at least one silicon main body with a charge-doped zone, a hole-doped zone' and a first surface, and
first metallic conductor tracks on the first surface of the at least one main body,
the method comprising the following steps:
a) providing a prepared solar module where the first metallic conductor tracks are accessible from an from an outside,
b) removing a removal portion of the at least one main body, wherein the first metallic conductor tracks are situated on the removal portion, and
c) collecting the removed material.

2. The method according to claim 1, wherein a removal tool is used to remove the removal portion, said removal tool penetrating with a penetration element into the at least one main body and breaking out the removal portion.

3. The method according to claim 2, wherein the removal tool penetrates into the at least one main body on a lateral surface of the at least one main body or through the first surface of the at least one main body

4. The method according to claim 2 wherein the removal tool comprises two penetration elements, each of which penetrates into the at least one main body on one side of the first metallic conductor tracks, so that the removal portion lies between the two penetration elements.

5. The method according to claim 1 wherein the at least one main body has a second surface opposite the first surface on which second metallic conductor tracks are located, wherein the removal portion contains part of the first surface with the first metallic conductor tracks and part of the second surface with the second metallic conductor tracks.

6. The method according to claim 5, wherein the first metallic conductor tracks and the second metallic conductor tracks lie opposite each other.

7. The method according to claim 5, wherein the first metallic conductor tracks or second metallic conductor tracks are covered by a carrier layer.

8. The method according to claim 1 wherein the solar module has a cover layer that is at least partially transparent to visible light, and has at least one adhesive layer arranged between the cover layer and the first metallic conductor tracks or second metallic conductor tracks, and further comprising the steps of heating the at least one adhesive layer and subsequently removing the cover layer from the at least one main body.

9. A device for performing a method according to claim 1 comprising a removal tool and a collection device.

10. The method according to claim 7 wherein the carrier layer is made of a plastic.
